(19) United States
(12) Patent Application Publication
(10) Pub. No.: US 2023/0087411 A1
(43) Pub. Date: Mar. 23, 2023

(54) Electronic Devices Having Quantum Film Infrared Sensors

(71) Applicant: Apple Inc., Cupertino, CA (US)

(72) Inventors: Xiaofan Niu, San Jose, CA (US); Tong Chen, Fremont, CA (US); Mark T. Winkler, San Jose, CA (US); Zachary M. Beiley, Oakland, CA (US); Andras G. Pattantyus-Abraham, Menlo Park, CA (US)

(21) Appl. No.: 17/483,660

(22) Filed: Sep. 23, 2021

(51) Int. Cl. H01L 25/16

(52) U.S. Cl. CPC H01L 25/167; H01L 31/0384

(57) ABSTRACT

An electronic device may include an infrared sensor with light sources and a quantum film photodetector. The light sources may emit short-wavelength infrared (SWIR) light through a display panel and the photodetector may receive the SWIR light through the panel after reflection off an object. The light sources and an integrated circuit may be mounted to a wall of a sensor module mounted to the panel. The module may include a lens. The photodetector may be disposed onto the rear wall, lens, integrated circuit, or display panel. The photodetector may include multiple types of quantum film to absorb different wavelengths of SWIR light. The SWIR light may pass through the display panel without distorting images emitted by the display panel. Using a quantum film in the photodetector may allow the photodetector to extend across a large surface area without unnecessarily increasing manufacturing cost for the device.

### FIELD

This application relates generally to electronic devices and, more particularly, to electronic devices with infrared light sensors.

### BACKGROUND

Electronic devices such as tablet computers, cellular telephones, and other equipment are sometimes provided with infrared light sensors. For example, infrared light sensors are often used to sense objects external to the electronic devices. It can be challenging to operate such sensors in the presence of other structures in the electronic device that block infrared light or that are otherwise affected by infrared light.

### SUMMARY

An electronic device may include and infrared sensor such as a quantum film infrared sensor. A quantum film is a light absorbing semiconductor thin film composed of colloidal quantum dots that have been mechanically and electronically coupled together by a cross-linking process. The quantum film infrared sensor may include light sources and one or more quantum film photodetectors. The electronic device may include a display panel with pixels that emit display light. The light sources may emit infrared light through the pixels of the display panel. The quantum film photodetector may receive the infrared light through the pixels of the display panel after the infrared light has reflected off an external object. The quantum film photodetector may generate sensor data based on the received infrared light. A sensor integrated circuit may read and process the sensor data.

The light sources and the sensor integrated circuit may be mounted to a rear wall of a sensor module. The sensor module may be mounted to the display panel. The sensor module may include a lens that at least partially overlaps the quantum film photodetector and that passes the reflected infrared light to the quantum film photodetector. The quantum film photodetector may be disposed (e.g., coated) onto the rear wall of the sensor module, onto the lens, onto the sensor integrated circuit, or onto the display panel external to the sensor module. The quantum film photodetector may include multiple types of quantum film (e.g., quantum dot species) that absorb different wavelengths of infrared light. The different species may be distributed across one or more layers. The device may include an array of quantum film photodetectors in one or more layers to allow for the capture of complex three-dimensional sensor data.

The light sources may emit the infrared light at short-wavelength infrared (SWIR) wavelengths to reduce distortion in the display pixel emission as the infrared light passes through the display panel. The SWIR wavelengths may include wavelengths that overlap spectral nulls in natural solar light. The quantum film photodetector may extend across a relatively large surface area, thereby maximizing signal-to-noise ratio of the sensor data, without unnecessarily increasing the manufacturing cost and difficulty of the device and without producing excessive dark current.

### BRIEF DESCRIPTION OF THE DRAWINGS

FIG. 1 is a schematic diagram of an illustrative electronic device in accordance with some embodiments.

FIG. 2 is a perspective view of an illustrative electronic device in accordance with some embodiments.

FIG. 3 is a cross-sectional side view of an illustrative electronic device having a quantum film infrared sensor that senses infrared light transmitted through a display in accordance with some embodiments.

FIG. 4 is a cross-sectional side view of an illustrative quantum film photodetector in accordance with some embodiments.

FIG. 5 is a top view of an illustrative quantum film in accordance with some embodiments.

FIG. 6 is a top view of an illustrative quantum film having multiple types of quantum dots for sensing different wavelengths of light in accordance with some embodiments.

FIG. 7 is a cross-sectional side view of multiple stacked quantum films having respective types of quantum dots for sensing different wavelengths of light in accordance with some embodiments.

FIG. 8 is a plot of sensing performance (external quantum efficiency) as a function of wavelength for illustrative quantum film photodetectors in accordance with some embodiments.

FIG. 9 is a cross-sectional side view of an illustrative quantum film photodetector having an overlapping bandpass filter, anti-reflective coating, and/or microlenses in accordance with some embodiments.

FIG. 10 is a perspective view of an illustrative quantum film photodetector that extends across a lateral area of a substrate in accordance with some embodiments.

FIG. 11 is a perspective view of an illustrative substrate having multiple quantum film photodetectors in accordance with some embodiments.

FIG. 12 is a cross-sectional side view of an illustrative quantum film infrared sensor module having one or more quantum film photodetectors layered onto a rear wall in accordance with some embodiments.

FIG. 13 is a cross-sectional side view of an illustrative quantum film infrared sensor module having one or more quantum film photodetectors layered onto a sensor integrated circuit in accordance with some embodiments.

FIG. 14 is a cross-sectional side view of an illustrative quantum film infrared sensor module having one or more quantum film photodetectors layered onto a lens in accordance with some embodiments.

FIG. 15 is a cross-sectional side view of an illustrative electronic device having one or more quantum film photodetectors layered onto a display panel in accordance with some embodiments.

### DETAILED DESCRIPTION

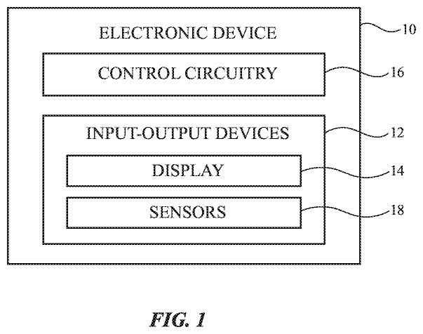

A schematic diagram of an illustrative electronic device that may include a quantum film infrared sensor is shown in FIG. 1. Electronic device 10 of FIG. 1 may be a computing device such as a laptop computer, a computer monitor containing an embedded computer, a tablet computer, a cellular telephone, a media player, or other handheld or portable electronic device, a smaller device such as a wristwatch or other device worn on a user's wrist, a pendant device, a headphone or earpiece device, a head-mounted device such as eyeglasses, goggles, or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment. Illustrative configurations in which device 10 is a portable device such as a wristwatch, cellular telephone, or tablet computer may sometimes be described herein as an example.

As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more processors, microprocessors, microcontrollers, digital signal processors, baseband processors, power management units, graphics processing units, audio chips, application specific integrated circuits, etc. Control circuitry 16 may include communications circuitry for supporting wired and/or wireless communications between device 10 and external equipment. For example, control circuitry 16 may include wireless communications circuitry such as cellular telephone communications circuitry and wireless local area network communications circuitry.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, haptic output devices, cameras, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be an organic light-emitting diode display, a display formed from an array of crystalline semiconductor light-emitting diode dies, a liquid crystal display, or other display. Display 14 may be a touch screen display that includes a layer of touch sensor electrodes or other touch-sensitive structures for gathering touch input from a user.

As shown in FIG. 1, input-output devices 12 may include sensors 18. Sensors 18 may include light sensors. The light sensors may include visible light sensors (e.g., sensors that sense light at optical wavelengths (e.g., 400-700 nm)) and/or infrared light sensors (e.g., sensors that sense light at infrared wavelengths greater than 700 nm). Sensors 18 may also include capacitive sensors, light-based proximity sensors, magnetic sensors, accelerometers, force sensors, touch sensors, fingerprint sensors, temperature sensors, pressure sensors, inertial measurement units, accelerometers, gyroscopes, compasses, microphones, radio-frequency sensors, three-dimensional image sensors (e.g., structured light sensors with light emitters such as infrared light emitters configured to emit structured light and corresponding infrared image sensors, three-dimensional sensors based on pairs of two-dimensional image sensors, etc.), cameras (e.g., visible light cameras and/or infrared light cameras), light-based position sensors (e.g., lidar sensors), monochrome and/or color ambient light sensors, and other sensors. Sensors 18 such as 2D and 3D image sensors, optical proximity sensors, lidar sensors, optical touch sensors, fingerprint sensors, and other sensors that use light and/or components that emit light such as status indicator lights and other light-emitting components may sometimes be referred to as optical components.

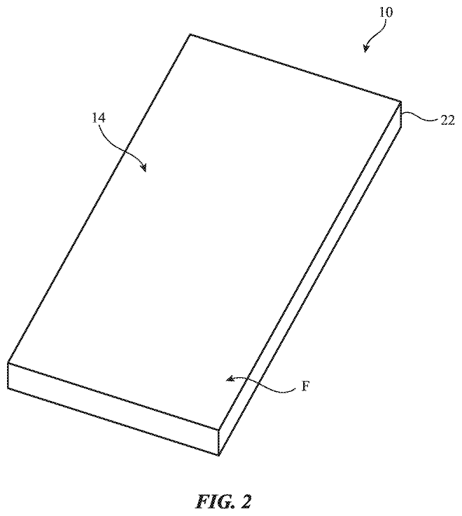

A perspective view of an illustrative electronic device of the type that may include a quantum film infrared sensor is shown in FIG. 2. In the example of FIG. 2, device 10 includes a display such as display 14 mounted in housing 22. Display 14 may be a liquid crystal display, a light-emitting diode display such as an organic light-emitting diode display or a display formed from crystalline semiconductor light-emitting diode dies, or other suitable display. Display 14 may have an array of image pixels extending across some or all of front face F of device 10 and/or other external device surfaces. The array of image pixels may be rectangular or may have other suitable shapes. Display 14 may be protected using a display cover layer (e.g., a transparent front housing layer) such as a layer of transparent glass, clear plastic, sapphire, or other clear layer. The display cover layer may overlap the array of image pixels.

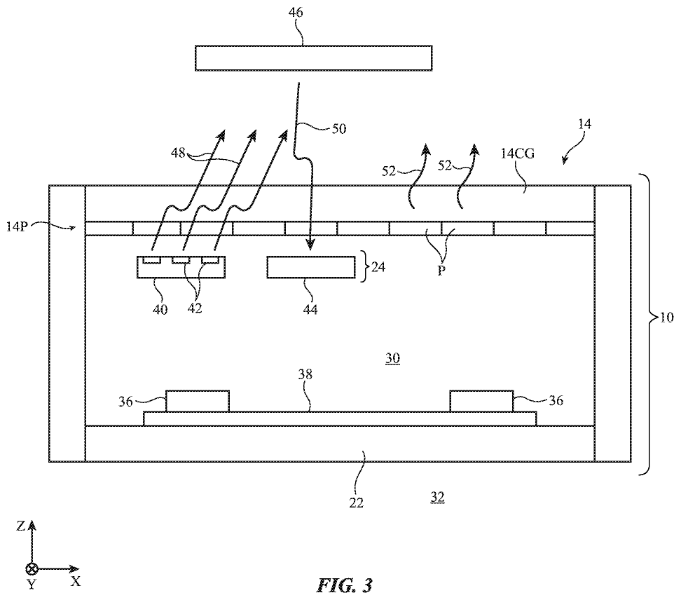

Housing 22, which may sometimes be referred to as an enclosure or case, may be formed of plastic, glass, ceramics, fiber composites, metal (e.g., stainless steel, aluminum, etc.), other suitable materials, or a combination of any two or more of these materials. As shown in the cross-sectional side view of device 10 of FIG. 3, housing 22 and display 14 may separate an interior region of device 10 such as interior region 30 from an exterior region surrounding device 10 such as exterior region 32. Housing 22 may be formed using a unibody configuration in which some or all of housing 22 is machined or molded as a single structure or may be formed using multiple structures (e.g., an internal frame structure, one or more structures that form exterior housing surfaces, etc.). If desired, a strap may be coupled to a main portion of housing 22 (e.g., in configurations in which device 10 is a wristwatch or head-mounted device). Internal electrical components 36 (e.g., integrated circuits, discrete components, etc.) for forming control circuitry 16 and input-output devices 12 may be mounted in interior region 30 of housing 22 (e.g., on one or more substrates such as printed circuit 38). In some configurations, components 36 may be attached to display 14 (e.g., circuitry may be mounted to the surface of display 14).

Display 14 may include a display panel such as display panel 14P that contains pixels P covered by display cover layer 14CG. Pixels P may emit display light 52 through display cover layer 14CG (e.g., for view by a user). Pixels P may include, for example, organic light emitting diode (OLED) pixels, light-emitting diode (LED) pixels, liquid crystal display (LCD) pixels, etc. Display light 52 may display images (e.g., where the light for each pixel of the image is emitted by a respective pixel P in display panel 14P). Display light 52 may be at visible wavelengths (e.g., 400-700 nm).

As shown in FIG. 3, device 10 may include a quantum film infrared light sensor such as quantum film infrared sensor 24 mounted within interior region 30. Quantum film infrared sensor 24 may be used to sense infrared light incident upon device 10 from exterior region 32. Quantum film infrared sensor 24 may include a light-emitting component such as light-emitting component 40. Quantum film infrared sensor 24 may also include a light detecting component such as quantum film photodetector 44. Quantum film infrared sensor 24 may sometimes be referred to herein as an optical transceiver (e.g., where light-emitting component 40 forms an optical transmitter and quantum film photodetector 44 forms an optical receiver for the optical transceiver). Light-emitting component 40 may include one or more light sources such as light sources 42. Light sources 42 (sometimes referred to as emitters) may emit light 48. Light sources 42 may include light-emitting diodes (LEDs) or lasers (e.g., vertical-cavity surface-emitting lasers, edge emitting lasers, etc.), as examples. Light sources 42 may be arranged in an array pattern if desired.

The pixels P of display 14 may cover all the front face of device 10 or display 14 may have pixel-free areas (e.g., notches, rectangular islands, inactive border regions, or other regions) that do not contain any pixels. Pixel-free areas may be used to accommodate an opening for a speaker and windows for optical components such as image sensors, an ambient light sensor, an optical proximity sensor, a three-dimensional image sensor such as a structured light three-dimensional image sensor, a camera flash, an illuminator for an infrared image sensor, an illuminator for a three-dimensional sensor such as a structured light sensor, a time-of-flight sensor, a lidar sensor, etc.

During operation of quantum film infrared sensor 24, light sources 42 may emit light 48 towards exterior region 32 (e.g., through pixels P of display 14). Light sources 42 may be used to illuminate an object external to device 10 such as external object 46 with light 48. External object 46 may be, for example, a user's hand, face, eye (e.g., a user's iris), finger, arm, leg, or other body part, may be another electronic device such as device 10, a peripheral device, an accessory device, a user input device, or a gaming controller, may be some or all of the body of a person other than the user of device 10, may be an animal or pet in exterior region 32, may be some or all of a vehicle or other animate object in exterior region 32, may be an inanimate object such as some or all of a piece of furniture, a wall, a ceiling, a floor, or a building, or may be any other suitable external object.

The light 48 emitted by light sources 42 may reflect off external object 46 as reflected light 50 (e.g., reflected light 50 may be a reflected version of light 48 that has reflected off external object 46). Reflected light 50 may pass from exterior region 32 to quantum film photodetector 44 in infrared light sensor 24 (e.g., through pixels P of display 14). Quantum film photodetector 44 may sense (detect) reflected light 50 (e.g., quantum film photodetector 44 may generate sensor data in response to reflected light 50). Control circuitry 16 (FIG. 1) may read and process the sensor data generated by quantum film photodetector 44 (e.g., control circuitry 16 may use quantum film photodetector 44 to sense reflected light 50 for further processing) and may process the light 48 emitted by light sources 42 to sense or detect one or more characteristics of external object 46 at one or more times.

Control circuitry 16 may, as examples, process light 48 and/or reflected light 50 to perform proximity sensing (e.g., to sense, detect, identify, compute, or determine the proximity, presence, and/or absence of external object 46 and/or the distance/displacement/velocity between external object 46 and device 10), to capture two-dimensional or three-dimensional images of external object 46 and/or other portions of exterior region 32, to identify physical features of external object 46 such as fingerprint ridges (e.g., quantum film infrared sensor 24 may be an optical fingerprint sensor that identifies a user or another person based on the user's fingerprint) and/or facial features (e.g., quantum film infrared sensor 24 may be a facial sensor that identifies a user or another person based on the user's facial features and/or that identifies facial expressions), to detect and/or track the direction of a user's gaze at one or more times (e.g., when external object 46 is a user's eye), to detect and/or track the location of object 46 over time, to detect physical gestures provided by a user or other persons as a user input to device 10, to perform optical communications with external object 46 (e.g., when external object 46 is includes optical communications equipment), to detect ambient light levels of exterior region 32, etc.

In general, it may be desirable for display 14 to include a relatively small pixel-free area to provide device 10 with as large a display area as possible. Some or all of quantum film infrared sensor 24 may therefore overlap pixels P in display panel 14P. However, if care is not taken, the components and materials of display panel 14P may block, absorb, diffract, and/or reflect light 48, thereby preventing light 48 from passing to exterior region 32.

To allow light 48 and reflected light 50 to pass through display panel 14P, light sources 42 may emit light 48 at wavelengths greater than 700 nm. In some scenarios, light 48 may be emitted at near-infrared (NIR) wavelengths between around 700 nm and 1100 nm. While these wavelengths may allow light 48 and reflected light 50 to pass through display panel 14P to exterior region 32, light 48 at NIR wavelengths may cause unsightly distortions in the display light 52 emitted by pixels P. For example, in implementations where display panel 14P is an OLED display panel, light 48 at NIR wavelengths can cause current distortion in the thin-film transistors (TFTs) of the display panel (e.g., due to absorption of the light in the polysilicon channel of the TFTs), resulting in distortion of the display light 52 emitted by the display panel in both intensity and time. In addition, light 48 at NIR wavelengths may cause trapping and accumulation of photoelectrons and carriers in the polysilicon and backfilm for display panel 14P, creating unsightly image sticking in display light 52.

Due to the silicon bandgap, photon absorption by polysilicon in display panel 14P falls off rapidly as wavelength increases. To allow light 48 to pass through display 14 without distorting display light 52, light sources 42 may emit light 48 at longer wavelengths than NIR wavelengths (e.g., wavelengths longer than around 1100 nm). In some implementations that are described herein as an example, light sources 42 may emit light 48 at short-wavelength infrared (SWIR) wavelengths between around 1100 nm and 1700 nm. If desired, the wavelength of light 48 may be selected to minimize the impact of ambient light (e.g., natural sunlight or artificial light sources in exterior region 32) on the sensor data captured using quantum film photodetector 44. For example, light sources 42 may emit light 48 at SWIR wavelengths between around 1090-1170 nm (e.g., at 1130 nm) and/or between around 1340-1420 nm (e.g., at 1380 nm) to align with spectral nulls in the emission profile of the sun, thereby minimizing interference by sunlight with the operation of quantum film photodetector 44 and maximizing sensor signal-to-noise ratio (SNR). Light 48 may therefore sometimes be referred to herein as infrared light 48 or SWIR light 48.

While transmitting light 48 at SWIR wavelengths may minimize absorption of image light 48 by display panel 14P and the corresponding distortion to display light 52, there is still a non-zero amount of absorption as light 48 and reflected light 50 passes through display 14. As such, quantum film photodetector 44 may need to have a relatively large surface area (light collecting area) (e.g., in the X-Y plane) to generate sensor data with sufficient SNR using reflected light 50. In some implementations, an indium gallium arsenide (InGaAs) on indium phosphide (InP) PIN photodetector is used to gather sensor data based on reflected light 50. However, InGaAs on InP photodetectors are difficult and costly to manufacture, particularly with the large surface areas needed to obtain a satisfactory SNR from reflected light 50. In other implementations, a germanium Ge or germanium-silicon (Ge—Si) is used to gather sensor data based on reflected light 50. However, Ge and Ge—Si photodetectors exhibit excessive dark current, particularly at the large surface areas needed to obtain satisfactory SNR from reflected light 50.

To minimize the manufacturing complexity and cost of device 10 while capturing sensor data with satisfactory SNR and minimal dark current, reflected light 50 may be captured (sensed) using quantum film photodetector 44. Quantum film photodetector 44 may include a photoreactive quantum film that is used to convert photons in reflected light 50 into electric charge (signals), which is read by control circuitry 16 (FIG. 1) as sensor data for further processing. A quantum film is a light absorbing semiconductor thin film composed of colloidal quantum dots that have been mechanically and electronically coupled together by a cross-linking process. While referred to herein as an infrared light sensor, quantum film infrared sensor 24 may additionally or alternatively be used to sense visible light, NIR light, or a combination of visible light, NIR light, SWIR light, and/or light of other wavelengths (e.g., light 48 may be transmitted at visible wavelengths, NIR wavelengths, SWIR wavelengths, and/or wavelengths longer than SWIR wavelengths).

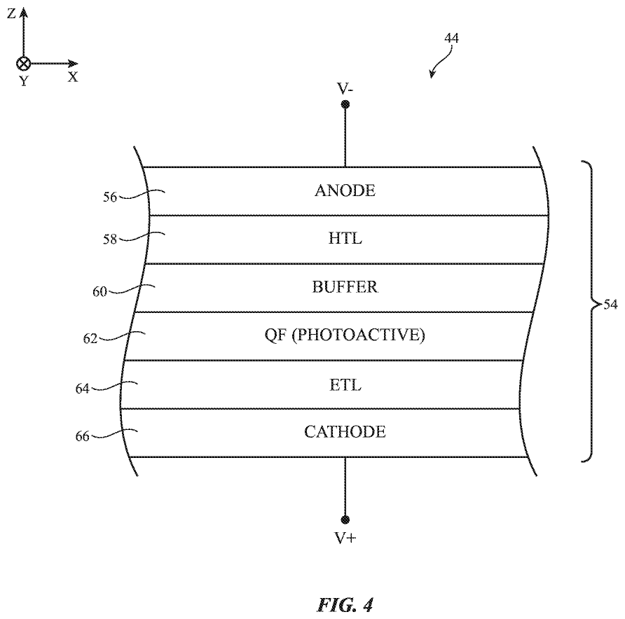

FIG. 4 is a cross-sectional side view of quantum film photodetector 44. As shown in FIG. 4, quantum film photodetector 44 may be formed from multiple layers in a semiconductor substrate such as substrate 54.

Quantum film photodetector 44 may include a cathode layer such as cathode 66.

Cathode 66 may include titanium nitride (TiN), titanium metal (Ti), tantalum (Ta), or tantalum nitride (TaN), as just a few examples. Quantum film photodetector 44 may also include an anode layer such as anode 56 opposite cathode 66. Anode 56 may include indium tin oxide (ITO) or other transparent conducting materials. Cathode 66 may receive a bias voltage V+. Anode 56 may receive a bias voltage V−. In other words, quantum film photodetector 44 may be reverse biased. This is merely illustrative and, if desired, quantum film photodetector 44 may be forward biased. As just one example, bias voltage V+ may be 0.5 V and bias voltage V− may be −2.0 V.

As shown in FIG. 4, quantum film photodetector 44 may include a hole transfer layer (HTL) such as HTL 58 interposed (stacked) between anode 56 and cathode 66. HTL 58 may, for example, include molybdenum trioxide (MoO3 stoichiometric or oxygen deficient (MoOx)), or other metal oxide semiconductors with satisfactory hole transport characteristics. Quantum film photodetector 44 may include a buffer layer such as buffer layer 60 interposed between HTL 58 and cathode 66. Buffer layer 60 may include aluminum oxide (Al2O3), as an example.

Quantum film photodetector 44 may also include an electron transfer layer (ETL) such as ETL 64 interposed between buffer layer 60 and cathode 66. ETL 64 may be formed from titanium oxide, titanium nitride, and/or zinc oxide (e.g., stacked titanium oxide, titanium nitride, and/or zinc oxide sublayers), for example. Quantum film photodetector 44 may include a photoactive quantum film (QF) layer such as quantum film 62 interposed between HTL 58 and ETL 64 (e.g., between buffer layer 60 and ETL 64). When biased by anode 56 and cathode 66, quantum film 62 may produce electric charge in response to photons of the reflected light 50 that passes through display 14 (FIG. 3). Quantum film 62 may, if desired, include multiple stacked quantum films such as a p-type quantum film layered onto an n-type quantum film.

The example of FIG. 4 is merely illustrative. The layers of substrate 54 may be provided in other orders. Buffer layer 60 may be located between other layers of quantum film photodetector 44. More than one buffer layer may be disposed within quantum film photodetector 44. Other layers may be added to quantum film photodetector 44 if desired. If desired, a portion of anode 56 and/or a portion of cathode 66 may be configured to form reflectors for reflected light 50. Additionally or alternatively, reflector layer(s) (e.g., a tantalum layer, portions of conductive vias such as copper vias in substrate 54 that are used to couple charge out of quantum film photodetector 44 and/or to bias quantum film photodetector 44, etc.) may be disposed on opposing sides of quantum film photodetector 44 in substrate 54 (e.g., under cathode 66 and/or over anode 56). The reflective layers may reflect the reflected light 50 incident on quantum film photodetector 44 back and forth within substrate 54 to help maximize absorption of the light by quantum film 62.

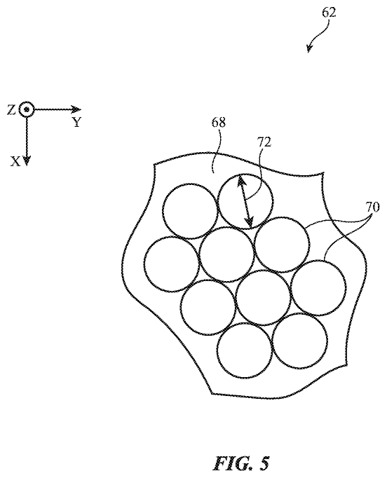

FIG. 5 is a top view of quantum film 62. As shown in FIG. 5, quantum film 62 may include a set of quantum dots (QDs) 70. Quantum dots 70 may be dispersed and cured into a film (quantum film 62) on an underlying carrier 68. Carrier 68 may include glass, polymer, flexible printed circuit material such as polyimide and copper clad, silicon wafer with or without integrated circuit, etc. As an example, quantum dots 70 may be synthesized to have a selected surface chemistry and width (size) 72. If desired, quantum dots 70 may be provided with insulating ligands which may be cut shorter prior to film deposition. Quantum dots 70 may be cross-linked to closely pack the quantum dots together during deposition on carrier 68. The composition, width 72, size distribution, and/or ligand composition of quantum dots 70 may be adjusted to tune the wavelengths at which quantum film 62 exhibits peak optical absorption. Quantum dots 70 may, for example, be configured to exhibit peak absorption at SWIR wavelengths such as 1090-1170 nm (e.g., at 1130 nm) or 1340-1420 nm (e.g., at 1380 nm).

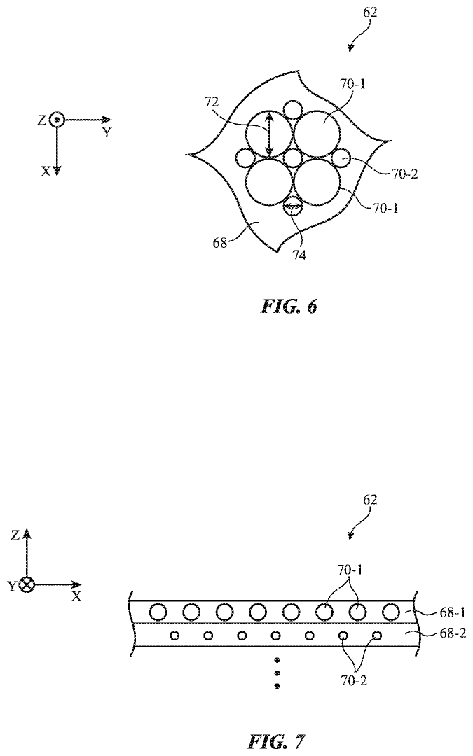

The example of FIG. 5 is merely illustrative. If desired, quantum film 62 may include multiple sets of quantum dots 70. FIG. 6 is a top view showing one example of how quantum film 62 may include multiple sets of quantum dots 70. As shown in FIG. 6, quantum film 62 may include a first set of quantum dots 70 such as quantum dots 70-1 and a second set of quantum dots 70 such as quantum dots 70-2 that have been dispersed and cured on carrier 68 (as quantum film 62). Quantum dots 70-1 may be of a different type or species than quantum dots 70-2. Quantum dots 70-1 may, for example, have width 72 whereas quantum dots 70-2 have width 74. Width 72 may configure quantum dots 70-1 to exhibit peak absorption at first SWIR wavelengths such as 1090-1170 nm (e.g., at 1130 nm) whereas width 74 configures quantum dots 70-2 to exhibit peak absorption at second SWIR wavelengths such as 1340-1420 nm (e.g., at 1380 nm).

The example of FIG. 6 is merely illustrative. If desired, quantum film 62 may include more than two types of quantum dots 70. This may, in general, allow light sources 42 of FIG. 3 to emit light 48 at any desired number of wavelength ranges, where each set of quantum dots in quantum film 62 has a respective width that configures that set of quantum dots to absorb a respective one of the wavelength ranges in reflected light 50. If desired, quantum film 62 may include multiple layers of quantum dots.

FIG. 7 is a cross-sectional side view showing one example of how quantum film 62 may include multiple layers of quantum dots. As shown in FIG. 7, quantum film 62 may include a first layer of quantum dots 70-1 (e.g., on a first carrier such as carrier 68-1) and a second layer of quantum dots 70-2 (e.g., on a second carrier such as carrier 68-2). One or more of the layers may have more than one type of quantum dot (e.g., for absorbing respective wavelengths) and/or there may be more than two layers, if desired.

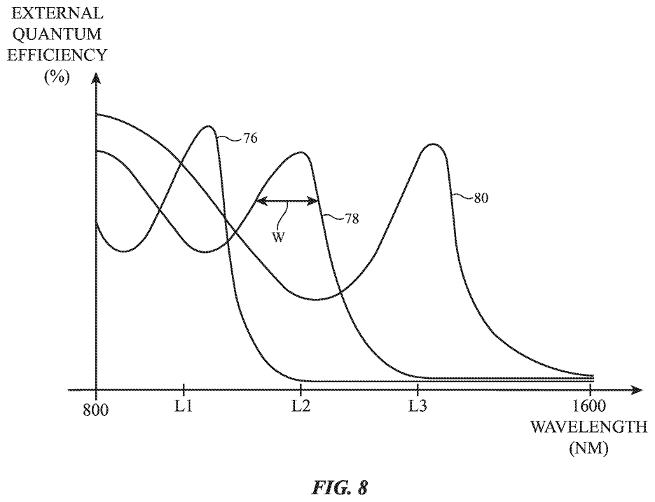

FIG. 8 is a plot of sensing performance (external quantum efficiency) as a function of wavelength for quantum film photodetector 44 when provided with different types of quantum dots in quantum film 62. As shown in FIG. 8, curve 76 plots the quantum efficiency of quantum film photodetector 44 when provided with a first type of quantum film (e.g., a quantum film having a first set of quantum dots 70 having a first width). As shown by curve 76, the first set of quantum dots may configure quantum film photodetector 44 to exhibit peak quantum efficiency and thus peak absorption for reflected light 50 at wavelength L1.

Curve 78 plots the quantum efficiency of quantum film photodetector 44 when provided with a second type of quantum film (e.g., a quantum film having a second set of quantum dots 70 having a first width). As shown by curve 78, the second set of quantum dots may configure quantum film photodetector 44 to exhibit peak quantum efficiency and thus peak absorption for reflected light 50 at wavelength L2 that is greater than wavelength L1.

Curve 80 plots the quantum efficiency of quantum film photodetector 44 when provided with a third type of quantum film (e.g., a quantum film having a third set of quantum dots 70 having a third width). As shown by curve 80, the third set of quantum dots may configure quantum film photodetector 44 to exhibit peak quantum efficiency and thus peak absorption for reflected light 50 at wavelength L3 that is greater than wavelength L2.

By adjusting the size of the quantum dots provided in quantum film 62, the quantum efficiency of quantum film photodetector 44 may be tuned to align with the wavelength range(s) of light 48. The size of the quantum dots may also be adjusted to tune the bandwidth W of quantum film photodetector 44. Wavelength L2 may be, for example, a wavelength between 1090-1170 nm (e.g., 1130 nm). Wavelength L3 may be, for example, a wavelength between 1340-1420 nm (e.g., 1380 nm). The wavelengths absorbed by quantum film 62 need not be SWIR wavelengths. For example, wavelength L1 may be 900-980 nm (e.g., 940 nm). Each of these wavelengths may correspond to spectral nulls in solar light produced naturally by the sun, thereby minimizing the effect of sunlight on quantum film photodetector 44, for example. Additionally or alternatively, the bandwidth and spectral response of the quantum dots may be tuned by adjusting their composition (e.g., PbSₓSe₁₋ₓ), and/or by changing the base semiconductor compound used to form the quantum dots (e.g., indium arsenide (InAs) vs lead sulfide (PbS)).

The quantum film 62 in quantum film photodetector 44 may include quantum dots 70 that configure quantum film photodetector 44 to exhibit the quantum efficiency associated with curve 78, curve 80, and/or curve 76. Using multiple sets of different types of quantum dots in quantum film 62 (e.g., at least quantum dots 70-1 and 70-2 of FIGS. 6 and 7) may configure quantum film photodetector 44 to exhibit two or more quantum efficiency peaks (e.g., as shown by the combination of curves 78, 80, and/or 76). This is merely illustrative and, in general, light sources 42 (FIG. 3) may emit light 48 in any desired wavelength bands and quantum film photodetector 44 may have a quantum film 62 that configures the quantum film photodetector to exhibit peak quantum efficiency in each of the wavelength bands.

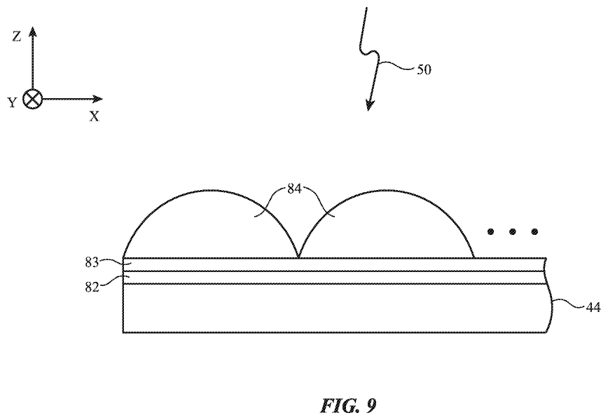

FIG. 9 is a cross-sectional side view showing how quantum film photodetector 44 may be provided with a bandpass filter, anti-reflective coating, and/or microlenses. As shown in FIG. 9, an optical filter such as bandpass filter (BPF) 82 may be layered onto and/or overlapping quantum film photodetector 44 (e.g., the side of quantum film photodetector 44 that receives reflected light 50 through the display). Bandpass filter 82 may have a pass band that aligns with the peak(s) in quantum efficiency for quantum film photodetector 44 (FIG. 8). This may, for example, minimize the amount of charge generated by quantum film photodetector in response to light other than the light 48 emitted by light sources 42 (FIG. 3).

An anti-reflective coating such as anti-reflective coating (ARC) 83 may be layered onto bandpass filter 82 overlapping quantum film photodetector 44. One or more microlenses such as microlenses 84 may be disposed onto and/or overlapping anti-reflective coating 83. Reflected light 50 may pass through microlens(es) 84, anti-reflective coating 83, and bandpass filter 82 to quantum film photodetector 44. Microlens(es) 84 may help to focus reflected light 50 onto the quantum film in quantum film photodetector 44, for example.

The example of FIG. 9 is merely illustrative. If desired, microlens(es) 84, anti-reflective coating 83, and/or bandpass filter 82 may be omitted. Microlens(es) 84, anti-reflective coating 83, and/or bandpass filter 82 need not be layered directly onto quantum film photodetector 44 and may, if desired, be spaced apart from quantum film photodetector 44. The relative positions of bandpass filter 82, anti-reflective coating 83, and/or microlens(es) 84 may be swapped if desired (e.g., bandpass filter 82 may be interposed between anti-reflective coating 83 and microlenses 84).

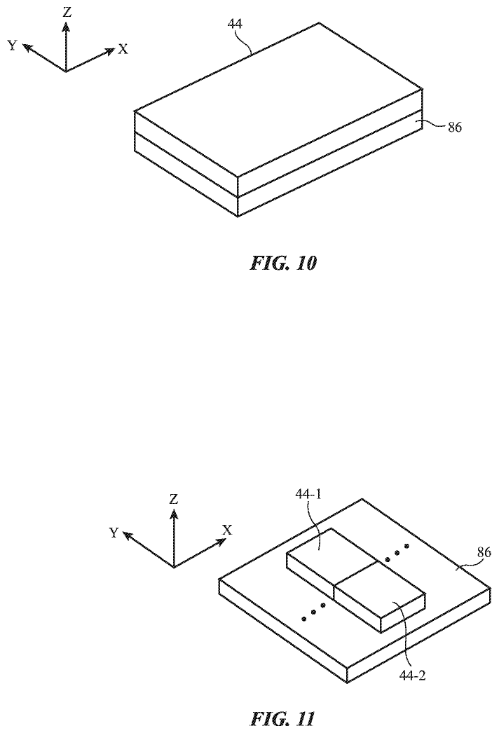

FIG. 10 is a perspective view showing how quantum film photodetector 44 may be mounted to an underlying substrate. As shown in FIG. 10, quantum film photodetector 44 may be mounted to substrate 86. Quantum film photodetector 44 may have a continuous light-receptive surface area that extends across a relatively large area of substrate 86. In the example of FIG. 10, quantum film photodetector 44 extends across all or substantially all the surface area of substrate 86.

The example of FIG. 10 is merely illustrative. If desired, device 10 may include multiple quantum film photodetectors 44 mounted to substrate 86. FIG. 11 is a perspective view showing one example of how quantum film photodetector 44 may be mounted to substrate 86. As shown in FIG. 11, there may be a set of N quantum film photodetectors 44 such as quantum film photodetectors 44-1 and 44-2 mounted to substrate 86. N may be any desired integer. This may, for example, allow each quantum film photodetector to serve as a sensing pixel for sensing reflected light 50 (e.g., to provide control circuitry 16 with spatial resolution or a spatial image of the reflected light 50). The N quantum film photodetectors may be arranged in a rectangular array pattern (e.g., a rectangular grid of quantum film photodetectors arranged in rows and columns) or in any other desired pattern on substrate 86.

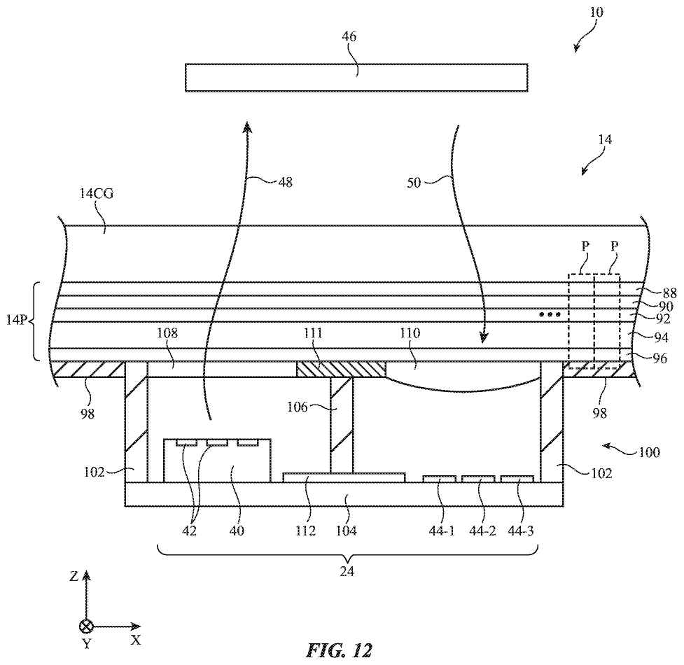

FIG. 12 is a cross-sectional side view showing one example of how quantum film infrared sensor 24 may be mounted within device 10 for transmitting light 48 and receiving reflected light 50 through display panel 14P. As shown in FIG. 12, display 14 may include display panel 14P layered onto the interior surface of display cover layer 14CG.

Display panel 14P may include multiple stacked (e.g., active) display panel layers. For example, display panel 14P may include a touch-sensitive layer on display cover layer 14CG such as touch sensor layer 88. Touch sensor layer 88 may include touch sensor electrodes such as ITO touch sensor electrodes that gather touch inputs for display 14.

Display panel 14P may include a light-emitting layer on touch sensor layer 88 such as OLED layer 90. This is merely illustrative and, if desired, OLED layer 90 may be replaced by an LED layer, LCD structures, or one or more layers of any other light emitting structures. OLED layer 90 may include cathodes, anodes, and light-emitting regions that emit display light (e.g., display light 52 of FIG. 3) of different colors. The light-emitting regions of OLED layer 90 may be driven using driving and routing layer 92. Driving and routing layer 92 may include a semiconductor substrate or another substrate, TFTs, conductive traces, conductive vias, and/or other components for driving image data onto OLED layer 90 for producing display light and/or for gathering touch sensor inputs using touch sensor layer 88.

Display panel 14P may include a backfilm layer on driving and routing layer 92 such as backfilm 94. Backfilm 94 may include polyethylene terephthalate (PET), as an example. If desired, display panel 14P may also include an adhesive layer on backfilm 94 such as adhesive layer 96. Adhesive layer 96 may help to mount other components to display panel 14P, for example. If desired, a conductive frame such as metal shield 98 may be layered under display panel 14P. Metal shield 98 may provide structural/mechanical support to display 14 and/or may help to prevent electromagnetic interference between the pixels P in display panel 14P and other components in device 10.

As shown in FIG. 12, quantum film infrared sensor 24 may be mounted within a sensor module 100. Sensor module 100 may be aligned with a hole, opening, or aperture in metal shield 98. Sensor module 100 may include a rear wall 104 that opposes display panel 14. Sensor module 100 may include sidewalls 102 that couple rear wall 104 to display panel 14P (e.g., sidewalls 102 may be attached, affixed, secured, or adhered to display panel 14P using adhesive layer 96 or may be pressed against display panel 14P using a foam spacer). Sidewalls 102 may be formed from conductive material. Rear wall 104 may include a printed circuit board (e.g., a rigid printed circuit board or a flexible printed circuit), other substrates, and/or a rigid conductive wall or shielding layer. The conductive material in sidewalls 102 and rear wall 104 may help to electromagnetically shield quantum film infrared sensor 24 from electromagnetic interference from other components in device 10, for example.

Sidewalls 102 may laterally surround sensor module 100 (e.g., in the X-Y plane). Sidewalls 102, rear wall 104, and display panel 14P may define a cavity within sensor module 100. Quantum film infrared sensor 24 may be disposed within the cavity of sensor module 100. For example, light-emitting component 40 may be mounted to rear wall 104. A dielectric window such as window 108 may layered onto display panel 14P overlapping the light sources 42 in light-emitting component 40. Light sources 42 may emit light 48 through window 108 and display 14. Window 108 may include glass, plastic, or other infrared-transparent materials, a lens that helps to focus or direct light 48, air, and/or filters that help to filter light 48 and/or to block exterior light from passing to light-emitting component 40. One or more quantum film photodetectors 44 may also be mounted to rear wall 104 (e.g., coated/deposited directly onto rear wall 104). In the example of FIG. 12, an array of quantum film photodetectors 44 (e.g., including at least quantum film photodetectors 44-1, 44-2, and 44-3) is disposed on rear wall 104 (e.g., rear wall 104 forms substrate 86 of FIGS. 10 and 11).

A conductive wall such as conductive midwall 106 may extend from rear wall 104 to display panel 14P between light-emitting component 40 and quantum film photodetectors 44 (e.g., conductive midwall 106 may divide the cavity in sensor module 100 into a first cavity that includes light-emitting component 40 and a second cavity that includes quantum film photodetectors 44). If desired, an absorbing layer such as absorber 111 may couple conductive midwall 106 to display panel 14P. Absorber 111 and conductive midwall 106 may help to mitigate cross-talk between light sources 42 and quantum film photodetectors 44 (e.g., where light 48 passes from light sources 42 to quantum film photodetectors 44 without first reflecting off external object 46).

Sensor module 100 may also include an in-module integrated circuit (IC) such as sensor IC 112 (e.g., an application-specific integrated circuit (ASIC) that forms part of control circuitry 16 of FIG. 1). Sensor IC 112 may include one or more processors that control (drive) light sources 42 to emit light 48, may provide bias voltages to quantum film photodetectors 44, may read sensor data from quantum film photodetectors 44, and/or may process the sensor data read from quantum film photodetectors 44. Sensor IC 112 may, for example, include an analog front end, one or more analog-to-digital converters (ADCs), data processing circuitry, and/or data communications circuitry. Sensor IC 112 may be mounted to rear wall 104 (e.g., at or under conductive midwall 106 or on either side of conductive midwall 106). If desired, conductive traces and conductive vias in rear wall 104 may route signals between light sources 42 and sensor IC 112 and may route signals between sensor IC 112 and quantum film photodetectors 44.

The light 48 transmitted through display 14 by light sources 42 may reflect off external object 46 as reflected light 50. A dielectric window may be layered onto display panel 14P overlapping the quantum film photodetectors 44. The window may include glass, plastic, or other infrared-transparent materials, a lens that helps focus or direct reflected light 50, and/or filters that help to filter light 48 and/or to block light other than reflected light 50 (e.g., other wavelengths of light) from passing to quantum film photodetectors 44. In the example of FIG. 12, the window includes a lens such as lens 110. Reflected light 50 may pass through display 14 and lens 110. Lens 110 may transmit and focus reflected light 50 onto quantum film photodetectors 44. In this way, quantum film infrared sensor 24 may gather sensor data from/about external object 46 through the active area of display 14 for performing further processing operations (e.g., proximity detection, gaze tracking, facial recognition, fingerprint sensing, object tracking, optical communications, etc.). Such sensor IC integration may also have other benefits such as, for example, increasing sensor speed/bandwidth, saving processing power, reducing external electromagnetic interference (EMI), etc.

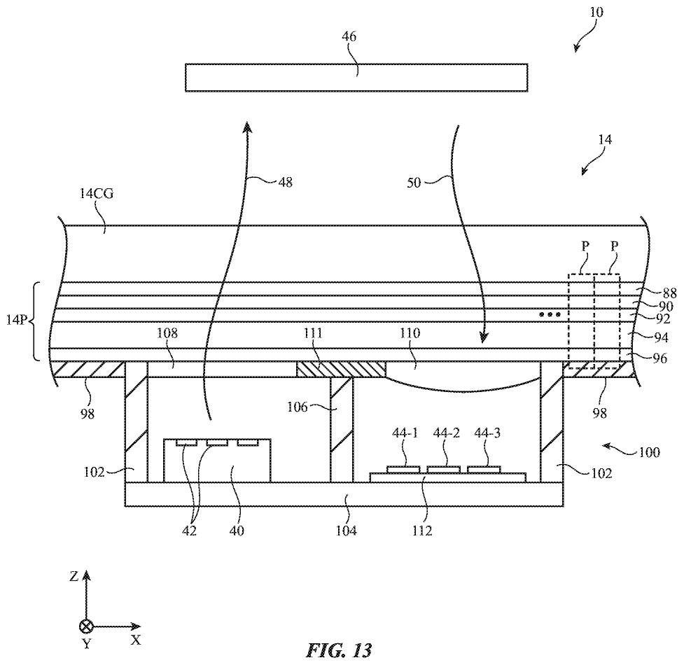

The example of FIG. 12 in which quantum film photodetectors 44 are mounted to rear wall 104 of sensor module 100 is merely illustrative. If desired, quantum film photodetectors 44 may be mounted to sensor IC 112 in sensor module 100, as shown in the example of FIG. 13 (e.g., where sensor IC 112 forms substrate 86 of FIGS. 10 and 11). As shown in FIG. 13, sensor IC 112 may overlap lens 110 (e.g., entirely to one side of conductive midwall 106). One or more quantum film photodetectors 44 (e.g., at least quantum film photodetectors 44-1, 44-2, and 44-3) may be disposed on sensor IC 112 (e.g., coated/deposited directly onto a surface of sensor IC 112). Mounting quantum film photodetectors 44 in this way may allow sensor IC 112 to directly drive and read quantum film photodetectors 44 without passing signals through rear wall 104, thereby minimizing the amount of space in device 10 consumed by sensor module 100 and/or maximizing the speed with which sensor IC 112 reads quantum film photodetectors 44, for example. Such sensor IC integration may also have other benefits such as, for example, increasing sensor speed/bandwidth, saving processing power, reducing external electromagnetic interference (EMI), etc.

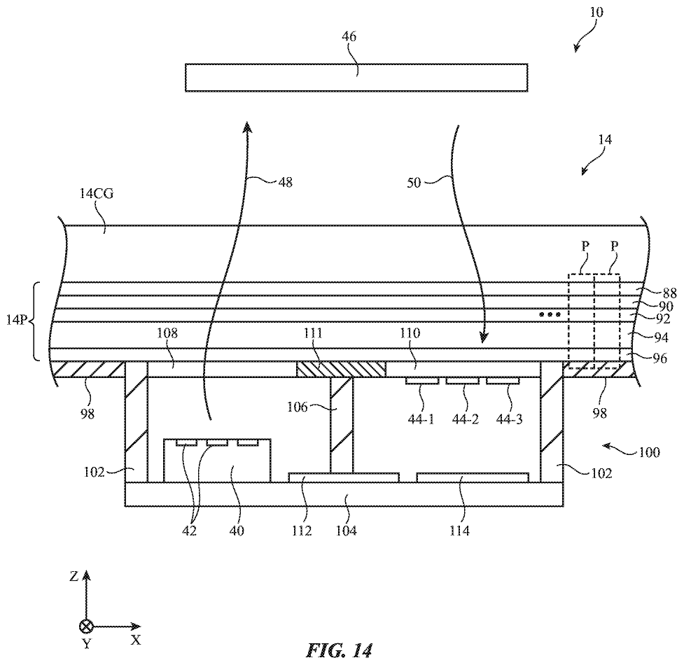

In other implementations, quantum film photodetectors 44 may be mounted directly to the window for sensor module 100, as shown in the example of FIG. 14. As shown in FIG. 14, one or more quantum film photodetectors 44 (e.g., at least quantum film photodetectors 44-1, 44-2, and 44-3) may be disposed on lens 110 (e.g., coated/deposited directly onto a surface of lens 110) or on other window structures on display panel 14P and overlapping quantum film photodetectors 44. In other words, lens 110 or the other window structures may form substrate 86 of FIGS. 10 and 11.

If desired, an additional sensor such as sensor 114 may be mounted to rear wall 104 (e.g., within the focal plane of lens 110). Sensor 114 may include one or more additional quantum film photodetectors 44, one or more InGaAs photodetectors, one or more silicon sensors, or other sensors for sensing reflected light 50. Sensor 114 may, for example, gather additional sensor data from any reflected light 50 that was not absorbed by quantum film photodetectors 44. If desired, sensor IC 112 may gather sensor data from the quantum film photodetectors 44 on lens 110 to sense reflected light 50 at the entrance pupil for sensor module 100. Sensor IC 112 may also gather sensor data from sensor 114 to sense reflected light 50 at the focal plane of lens 110. Sensor IC 112 may process the sensor data from the entrance pupil and sensor data from the focal plane to recover a three-dimensional optical field of reflected light 50 (e.g., for generating a three-dimensional infrared reconstruction of external object 46). If desired, the quantum film photodetectors on lens 110 may include multiple layers of quantum film photodetectors 44 and, if desired, each layer may have a different absorption wavelength, active area, pixel pitch, and/or array pattern to allow sensor IC 112 to perform advanced spatial and spectral sensing of reflected light 50.

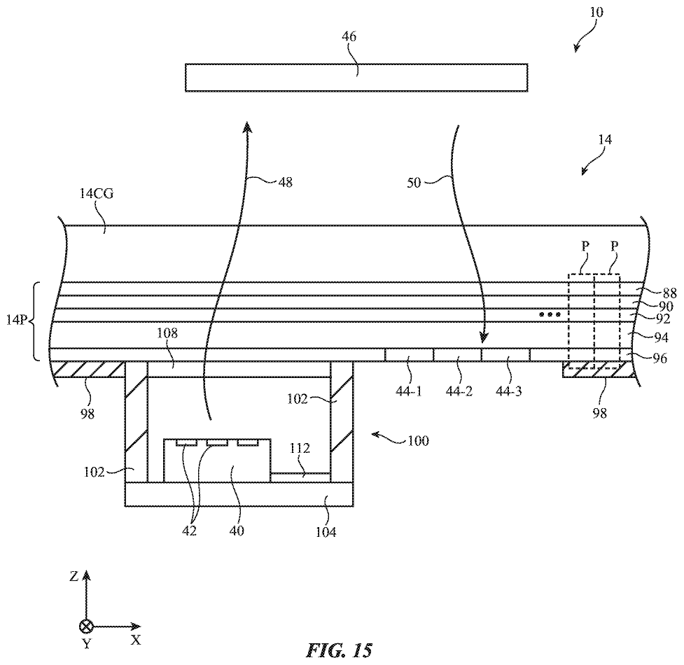

In other implementations, quantum film photodetectors 44 may be mounted directly to display panel 14P and external to sensor module 100, as shown in the example of FIG. 15. As shown in FIG. 15, one or more quantum film photodetectors 44 (e.g., at least quantum film photodetectors 44-1, 44-2, and 44-3) may be disposed on display panel 14P (e.g., coated/deposited directly onto a surface of display panel 14P). In the example of FIG. 15, quantum film photodetectors 44 are disposed on backfilm 94 of display panel 14P. This is merely illustrative and, if desired, quantum film photodetectors 44 may be disposed on (e.g., disposed or coated directly onto) adhesive layer 96, driving and routing layer 92, OLED layer 90, touch sensor layer 88, display cover layer 14CG, or onto a flexible printed circuit that is pressed against display panel 14P within the aperture of metal shield 98.

If desired, driving and routing layer 92 may be used to route signals between quantum film photodetectors 44 and sensor IC 112 within sensor module 100 or mounted elsewhere in device 10. If desired, the quantum film photodetectors on display panel 14P may include multiple layers of quantum film photodetectors 44 and zero, one, or more than one of the layers may be layered onto one or more of adhesive layer 96, driving and routing layer 92, OLED layer 90, touch sensor layer 88, and display cover layer 14CG. If desired, each layer may have a different absorption wavelength, active area, pixel pitch, and/or array pattern to allow sensor IC 112 to perform advanced spatial and spectral sensing of reflected light 50.

In the examples of FIGS. 12-15, quantum film infrared sensor 24 includes an array of quantum film photodetectors 44 (e.g., including at least quantum film photodetectors 44-1, 44-2, and 44-3). This is merely illustrative. In general, the array of quantum film photodetectors in FIGS. 12-15 may include any desired number N of quantum film photodetectors 44 arranged in any desired pattern or may include a single quantum film photodetector 44 (e.g., as shown in FIG. 10) that covers as large a surface area of rear wall 104 (FIG. 12), sensor IC 112 (FIG. 13), lens 110 (FIG. 14), or display panel 14P (FIG. 15) as possible. The arrangements of FIGS. 12, 13, 14, and/or 15 may be combined if desired (e.g., quantum film photodetectors 44 may be located at any desired combination of on rear wall 104, on sensor IC 112, on lens 110, and on display panel 14P).

Device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

Table of Reference Numerals

| | | | |
|---|---|---|---|
| 10 | Electronic device | 12 | Input-output devices |
| 14 | Display | 14P | Display panel |
| 14CG | Display cover layer | 16 | Control circuitry |
| 18 | Sensors | 22 | Housing |
| P | Pixel | F | Front Face |
| 24 | Quantum film infrared | 30 | Interior region |
| | sensor | | |
| 32 | Exterior region | 36 | Electrical |
| | | | components |
| 38 | Printed Circuit | 40 | Light-emitting |
| | | | component |
| 42 | Light source | 44, 44-1, | Quantum film |
| | | 44-2, 44-3 | photodetector |
| 46 | External object | 48 | Light |
| 50 | Reflected light | 52 | Display light |
| 54 | Substrate | 56 | Anode |
| 58 | HTL | 60 | Buffer layer |
| 62 | Quantum film | 64 | ETL |
| 66 | Cathode | 68, 68-1, | Carrier |
| | | 68-2 | |
| 70. 70-1, 70-2 | Quantum dots | 72, 74 | Width |
| 76, 78, 80 | Curve | W | Bandwidth |
| 82 | Bandpass filter | 83 | Anti-reflective |
| | | | coating |
| 84 | Microlens | 86 | Substrate |
| 88 | Touch sensor layer | 90 | OLED layer |
| 92 | Driving and routing | 94 | Backfilm |
| | layer | | |
| 96 | Adhesive layer | 98 | Metal shield |
| 100 | Sensor module | 102 | Sidewalls |
| 104 | Rear wall | 106 | Conductive midwall |
| 108 | Window | 110 | Lens |
| 111 | Absorber | 112 | Sensor IC |
| 114 | Sensor | | |

What is claimed is:

1. An electronic device comprising:
a display cover layer;
a display panel mounted to the display cover layer and configured to emit visible light through the display cover layer;
a light source configured to emit infrared light through the display panel; and
a quantum film photodetector configured to detect, through the display panel, the infrared light after the infrared light has reflected off an external object.

2. The electronic device of claim 1, further comprising:
a sensor module mounted to the display panel, wherein the light source and the quantum film photodetector are in the sensor module.

3. The electronic device of claim 2, wherein the sensor module comprises:
a substrate, the light source being mounted to the substrate; and
sidewalls that couple the substrate to the display panel.

4. The electronic device of claim 3, wherein the quantum film photodetector is disposed on the substrate.

5. The electronic device of claim 3, further comprising:
an integrated circuit (IC) mounted to the substrate, wherein the IC is configured to drive the light source and is configured to read sensor data from the quantum film photodetector, the quantum film photodetector being disposed on the IC.

6. The electronic device of claim 3, wherein the sensor module comprises:
a lens on the display panel, wherein the quantum film photodetector is disposed on the lens.

7. The electronic device of claim 6, further comprising:
a sensor on the substrate within a focal plane of the lens, wherein the quantum film photodetector and the sensor are configured to generate sensor data based on the infrared light that has reflected off the external object.

8. The electronic device of claim 1, wherein the quantum film photodetector is layered onto the display panel.

9. The electronic device of claim 8, wherein the display panel comprises at least a first layer and a second layer stacked on the first layer, the quantum film photodetector is layered onto the first layer, and the electronic device further comprises an additional quantum film photodetector layered onto the second layer.

10. The electronic device of claim 1, wherein the quantum film comprises a set of quantum dots deposited on a carrier.

11. The electronic device of claim 10, wherein the set of quantum dots is configured to absorb infrared light at a first wavelength and the quantum film comprises a second set of quantum dots configured to absorb infrared light at a second wavelength that is different from the first wavelength.

12. The electronic device of claim 11, wherein the second set of quantum dots is deposited on the carrier.

13. The electronic device of claim 11, wherein the second set of quantum dots is deposited on an additional carrier stacked onto the carrier.

14. The electronic device of claim 11, wherein the first wavelength comprises a wavelength between 1090-1170 nm and the second wavelength comprises a wavelength between 1340-1420 nm.

15. An electronic device comprising:
a display panel configured to emit display light; and
a quantum film photodetector configured to detect light at a wavelength greater than 700 nm that has been transmitted through the display panel.

16. The electronic device of claim 15, wherein the wavelength is between 1100 nm and 1700 nm.

17. The electronic device of claim 15, wherein the display panel comprises an organic light emitting diode (OLED) display panel.

18. The electronic device of claim 15, further comprising:
a substrate; and
an array of quantum film photodetectors that includes the quantum film photodetector and that is configured to detect the light at the wavelength that has been transmitted through the display panel.

19. An electronic device comprising:
a housing;
a display mounted to the housing and having a display panel with pixels configured to emit visible light; and
a sensor module mounted to the display panel, wherein the sensor module comprises:
a light-emitting component configured to emit short-wavelength infrared (SWIR) light through the pixels of the display panel,
a photodetector having a film of quantum dots configured to receive the SWIR light through the pixels of the display panel and configured to generate sensor data based on the received SWIR light, and
an integrated circuit configured to read the sensor data from the photodetector.

20. The electronic device of claim 19, wherein the sensor module comprises:
a rear wall, the light-emitting component and the integrated circuit being mounted to the rear wall;
sidewalls that couple the rear wall to the display panel; and
a midwall that separates the light-emitting component from the photodetector.
